(19) United States
(12) Patent Application Publication
(10) Pub. No.: US 2024/0404893 A1
(43) Pub. Date: Dec. 5, 2024

(54) APRIORI APPLICATION WITH DYNAMIC DIGITAL CORRECTION (DDC) FUNCTION

(71) Applicant: Applied Materials, Inc., Santa Clara, CA (US)

(72) Inventors: Shih-Hao KUO, Hsinchu City (TW); Shih-Hsien LEE, Hsinchu City (TW); Thomas L. LAIDIG, Richmond, CA (US); Jang Fung CHEN, Cupertino, CA (US); Min Sheng SUEN, Tainan City (TW)

(21) Appl. No.: 18/677,184

(22) Filed: May 29, 2024

Related U.S. Application Data
(60) Provisional application No. 63/469,852, filed on May 31, 2023.

(51) Int. Cl. H01L 21/66; H01L 23/495

(52) U.S. Cl. CPC H01L 22/20; H01L 23/49503

(57) ABSTRACT

Embodiments of the present disclosure generally relate to lithography systems. In one embodiment, a method is disclosed. The method includes measuring a location of a die pad of a die placed on a substrate and determining a die pad shift between an expected location of the die pad and the measured location of the die pad. The method also includes using the determined die pad shift and an expected via location to generate a shifted via location for a via electrically connecting to the die pad. The method further includes patterning the via at the shifted via location with a maskless lithography tool and utilizing a physical mask with a mask-based lithography tool to pattern a redistribution layer (RDL) pad electrically connected to the via patterned at the shifted via location with the maskless lithography tool.

### CROSS-REFERENCE TO RELATED APPLICATIONS

This application claims priority to U.S. Provisional Patent Application Ser. No. 63/469,852 filed on May 31, 2023, which is herein incorporated by reference in its entirety.

### BACKGROUND

### Field

Embodiments of the present disclosure generally relate to lithography systems. More particularly, embodiments of the present disclosure relate to a system, a software application, and a method of lithography for semiconductor packaging.

### Description of the Related Art

Electronic packaging and assembly are typically used to link the small dimensions of an integrated circuit (IC) to an interconnecting substrate, for example, a printed circuit board (PCB) or an interposer. The PCB usually includes a number of passive components and ICs to build a microelectronic device, and the interposer is a connection board embedded into a packaged chip with a plurality of chiplet ICs on the interposer. As the semiconductor industry has experienced rapid growth due to ongoing improvements in the integration density of a variety of electronic components, for example, transistors, diodes, resistors, and capacitors. For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

For the foregoing reasons, there is a need for a system, a software application, and method of lithography for semiconductor packaging.

### SUMMARY

Embodiments of the present disclosure generally relate to lithography systems. More particularly, embodiments of the present disclosure relate to a system, a software application, and a method of lithography for semiconductor packaging.

In one embodiment, a method is disclosed. The method includes measuring a location of a die pad of a die placed on a substrate and determining a die pad shift between an expected location of the die pad and the measured location of the die pad. The method also includes using the determined die pad shift and an expected via location to generate a shifted via location for a via electrically connecting to the die pad. The method further includes patterning the via at the shifted via location with a maskless lithography tool and utilizing a physical mask with a mask-based lithography tool to pattern a redistribution layer (RDL) pad electrically connected to the via patterned at the shifted via location with the maskless lithography tool.

In another embodiment, a layer structure is disclosed. The layer structure includes one or more die pads, the one or more die pads each comprising a die pad center point. The layer structure also includes one or more vias located above the one or more die pads, the one or more vias each comprising a via center point. The layer structure further includes one or more redistributed metal layer (RDL) pads located above the one or more vias, the one or more RDL pads each comprising a RDL pad center point, wherein the die pad center point, the via center point, and the RDL pad center point are unaligned, and the via center point is located between the RDL pad center point and the die pad center point.

In yet another embodiment, a non-transitory computer-readable medium is disclosed. The non-transitory computer-readable medium storing instructions that, when executed by a processor, cause a computer system to perform the steps of: calculating a correction factor, the calculation comprising: a via radius; a redistributed metal layer (RDL) pad radius; and a die pad radius. The steps also including determining one or more shifted die pad coordinates, and moving one or more via coordinates utilizing the correction factor, each via coordinates being moved to shifted via coordinates between theoretical die pad coordinates and shifted die pad coordinates of the one or more shifted die pad coordinates.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

The disclosure contains at least one drawing executed in color. Copies of this disclosure with color drawings will be provided to the Office upon request and payment of the necessary fee. As the color drawings are being filed electronically via EFS-Web, only one set of the drawings is submitted.

FIG. 1 is a schematic diagram of a lithography system in accordance with one or more embodiments of the present disclosure.

FIG. 2A is a perspective view of a maskless lithography tool that may benefit from embodiments described herein.

FIG. 2B is a schematic, cross-sectional view of a lithography tool in accordance with one or more embodiments of the present disclosure.

FIG. 3A is a schematic view of a portion of a mask pattern in accordance with one or more embodiments of the present disclosure.

FIG. 3B is a cross-sectional view of a layer structure with a theoretical die pad position in accordance with one or more embodiments of the present disclosure.

FIG. 4 is a schematic view of the interface in accordance with one or more embodiments of the present disclosure.

FIG. 5 is a schematic, top view of a packaging substrate prior to a first operation of the digital dynamic connection method described herein.

FIG. 6 is a flow diagram of a digital dynamic connection method in accordance with one or more embodiments of the present disclosure.

FIG. 7A is a schematic, top view of a layer structure after the correction of the via position to a partially shifted via position in accordance with one or more embodiments of the present disclosure.

FIG. 7B is a schematic, cross-sectional view of a layer structure in accordance with one or more embodiments of the present disclosure.

FIG. 8A is a schematic, top view of a layer structure without the RDL position after the correction of the via position to a shifted via position, according to one embodiment of the present disclosure.

FIG. 8B is a schematic, top view of a layer structure without the RDL position after the correction of the via position to a partially shifted via position, according to one embodiment of the present disclosure.

FIG. 9A is a schematic, top view of a layer structure after the correction of the via position to a shifted via position, according to one embodiment of the present disclosure.

FIG. 9B is a schematic, top view of a layer structure after the correction of the via position to a partially shifted via position, according to one embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to lithography systems. More particularly, embodiments of the present disclosure relate to a system, a software application, and method of lithography for semiconductor packaging.

In the advanced packaging industry, a die pad position of a semiconductor package will have unexpected drift due to the die pick and placement. For proper electrical connection, the top and bottom surface area of a via are between the die pad with a redistributed metal layer (RDL) pad. In some methods suitable for traditional litho-tool of correcting the die pad position drift, the die pad size and other characteristic feature dimensions of the die pad are enlarged to cover the variation caused by the die position drift. However, enlarging the feature dimensions will reduce I/O density, increase power consumption, and decrease chip performance. In other methods of adjusting for the die pad position drift, the die pad characteristic feature dimensions remain unadjusted, but the RDL pad and the via position are moved by a maskless lithography tool to compensate for the die pad shift. However, movement of the RDL pad and via position requires a direct-writing litho-tool (or maskless lithography tool). Due to the movement of the RDL pad position, the traditional litho-tool with a physical mask is unable to properly pattern the RDL pad positions.

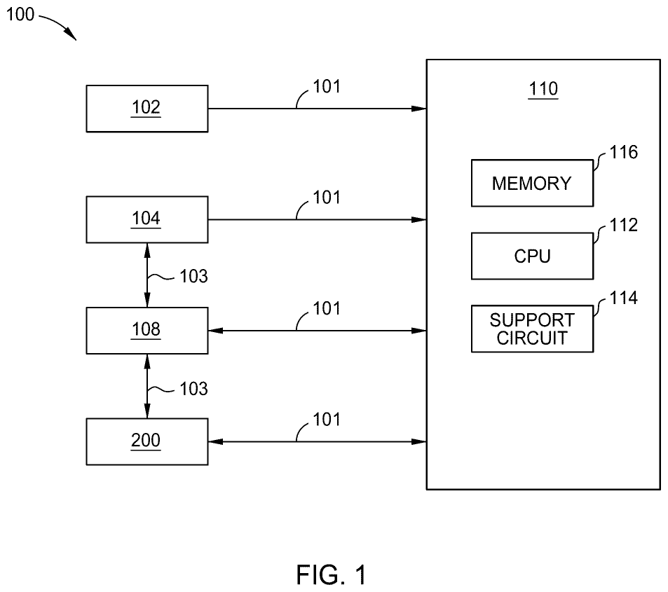

FIG. 1 is a schematic diagram of a lithography system 100 in accordance with one or more embodiments of the present disclosure. As shown, the lithography system 100 includes, but is not limited to, a pattern generator 102, a metrology device 104, a maskless lithography tool 108, a controller 110, and a plurality of communication links 101. The lithography system 100 may further include a transfer system 103. The maskless lithography tool 108 and the metrology device 104 may be connected by the transfer system 103. The transfer system 103 is operable to transfer a substrate from the metrology device 104 to and from the maskless lithography tool 108. In some embodiments, the transfer system 103 may also be operable to transfer the substrate to and from the maskless lithography tool 108 to the lithography tool 200, i.e. mask-based lithography tool.

Each of the lithography system devices (the pattern generator 102, the metrology device 104, and the maskless lithography tool 108) are operable to be connected to the controller 110 via the communication links 101. The lithography system 100 can be located in the same area or production facility, or the each of the lithography system devices can be located in different areas.

Each of the pattern generator 102, the metrology device 104, the maskless lithography tool 108, and controller 110 include an on-board processor and memory, where the memory is configured to store instructions corresponding to any portion of the digital dynamic connection method 600 described below. The communication links 101 may include at least one of wired connections, wireless connections, satellite connections, and the like. The communications links 101 facilitate sending and receiving files to store data, according to embodiments further described herein. Transfer of data along communications links 101 can include temporarily or permanently storing files or data in the cloud, before transferring or copying the files or data to a lithography environment device.

The controller 110 includes a central processing unit (CPU) 112, support circuits 114 and memory 116. The CPU 112 can be one of any form of computer processor that can be used in an industrial setting for controlling the lithography system devices. The memory 116 is coupled to the CPU 112. The memory 116 can be one or more of readily available memory, such as random access memory (RAM), read only memory (ROM), floppy disk, hard disk, or any other form of digital storage, local or remote. The support circuits 114 are coupled to the CPU 112 for supporting the processor in a conventional manner. These circuits include cache, power supplies, clock circuits, input/output circuitry, subsystems, and the like. The controller 110 can include the CPU 112 that is coupled to input/output (I/O) devices found in the support circuits 114 and the memory 116. The controller 110 is operable to facilitate and transfer a design file to the maskless lithography tool 108 via the communication links 101.

The memory 116 can include one or more software applications, such as a controlling software program. The memory 116 can also include stored media data that is used by the CPU 112 to perform the digital dynamic connection method 600 described herein. The CPU 112 can be a hardware unit or combination of hardware units capable of executing software applications and processing data. In some configurations, the CPU 112 includes a central processing unit (CPU), a digital signal processor (DSP), an application-specific integrated circuit (ASIC), and/or a combination of such units. The CPU 112 is generally configured to execute the one or more software applications and process the stored media data, which can be each included within the memory 116. The controller 110 controls the transfer of data and files to and from the various lithography system devices. The memory 116 is configured to store instructions corresponding to any operation of the digital dynamic connection method 600 according to embodiments described herein.

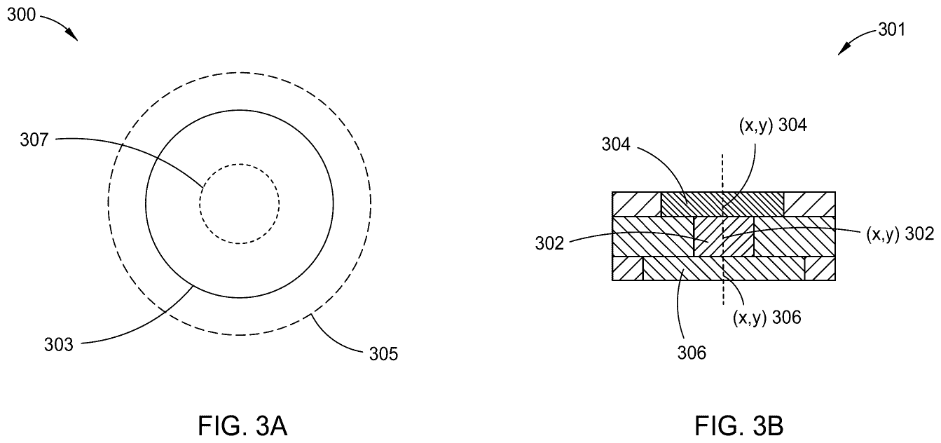

The pattern generator 102 may include software and hardware to create a graphic data system (GDS) design, a virtual mask software application (such as vMASC software), perform a data transfer, and generate an output file of a mask pattern 300 (as shown in FIG. 3A). The pattern generator 102 may be utilized to create the mask pattern 300 prior to operation 610 of the digital dynamic connection method 600. The mask pattern 300 generated in the pattern generator 102 may be sent to the controller 110 via the communication link 101.

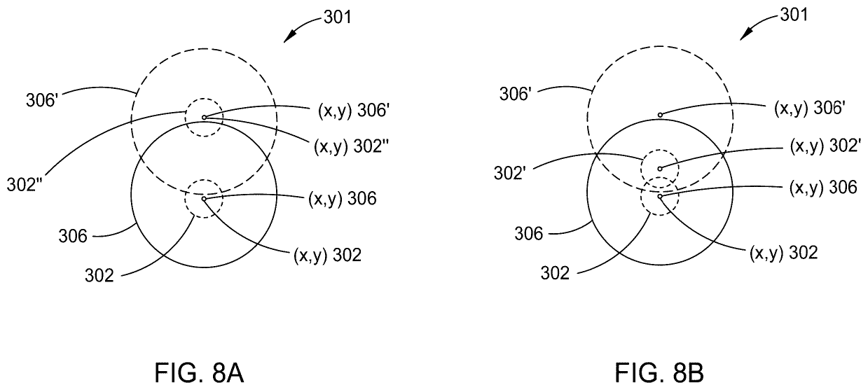

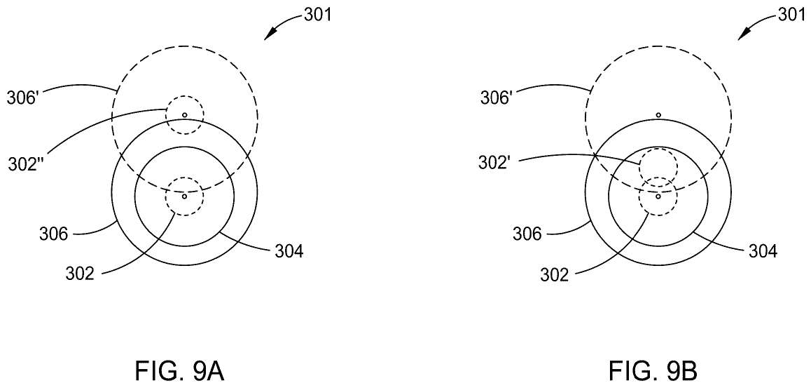

The metrology device 104 may include software and hardware to print on a substrate, measure die shift and/or rotation, convert die shift and rotation data into a format, and transfer the data to the controller 110. The metrology data generated from the metrology device 104 may be sent to the controller 110 via the communication link 101. The controller 110 may update the mask pattern 300 with the metrology data generated via the metrology device 104 to generate a compensated pattern with partially shifted via positions 302′ (as shown in FIGS. 8B and 9B).

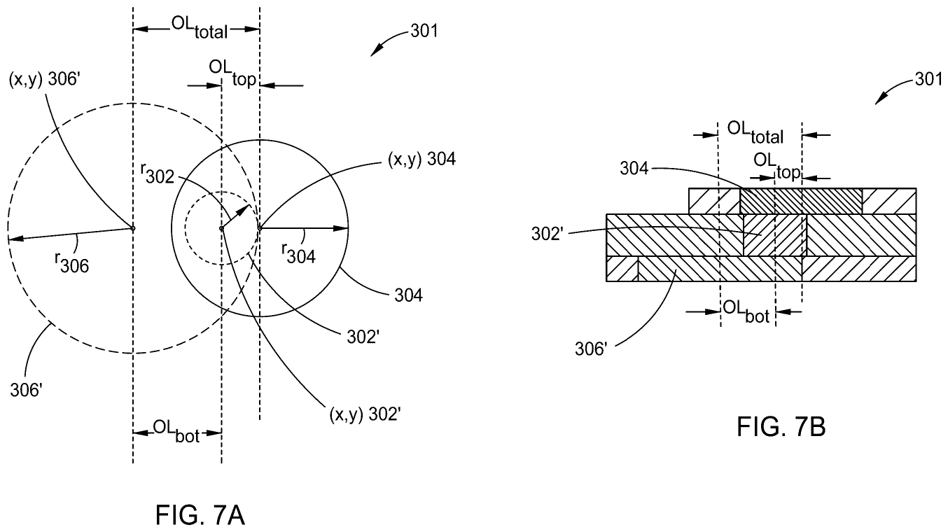

The compensated pattern with the partially shifted via positions 302′ is sent from the controller 110 to the maskless lithography tool 108 via the communication link 101. The maskless lithography tool 108 may include software and/or hardware to load a substrate, level the substrate, home the laser, find the edge of the substrate, pre-focus the laser, align the laser on the substrate, and perform laser printing. In some embodiments, the maskless lithography tool 108 may not be utilized to pattern the RDL pad positions 304 (shown in FIG. 7A). The lithography tool 200 may be utilized to pattern the RDL pad positions 304.

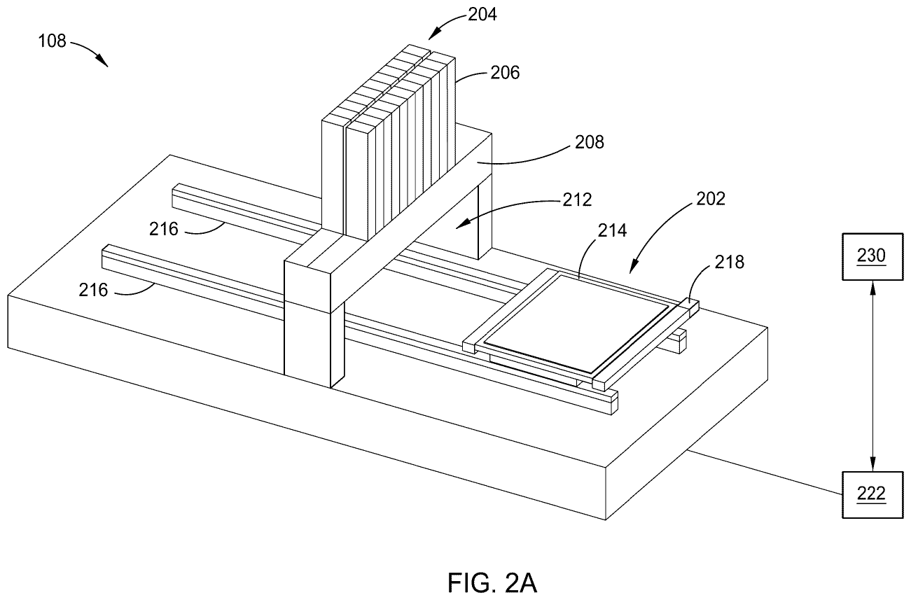

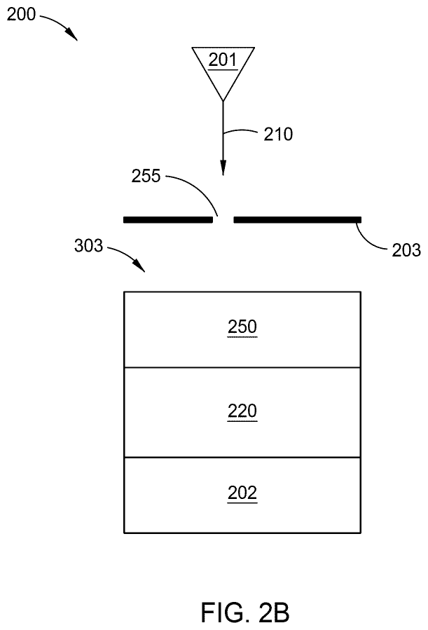

FIG. 2A is a perspective view of an exemplary maskless lithography tool 108, such as a maskless lithography system, that may benefit from embodiments described herein. The maskless lithography tool 108 includes a stage 202 and a processing unit 204. The chuck 214 on the stage 202 is supported by track motors 216. A packaging substrate 220 is supported by the chuck 214. The chuck 214 is operable to move along the track motors 216 to move the substrate 220 to a specific position. A position sensor 218 is coupled to the stage 202 in order to provide information of the position of the chuck 214 to a lithography controller 222.

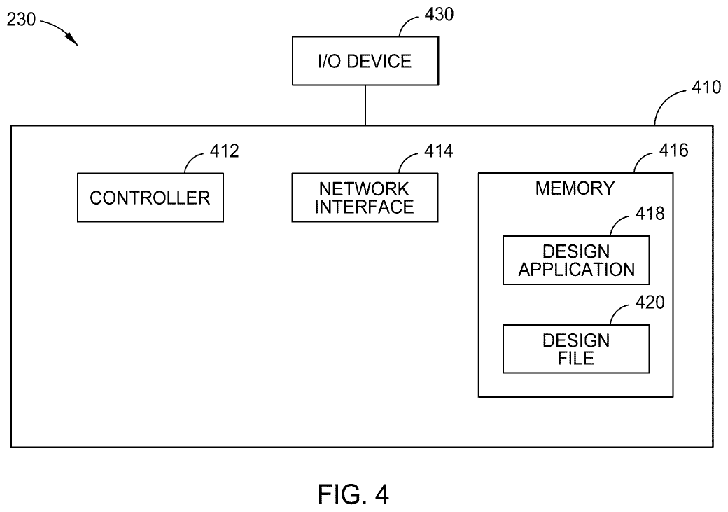

The lithography controller 222 is generally designed to facilitate the control and automation of the processing techniques described herein. The lithography controller 222 may be coupled to or in communication with the processing unit 204, the stage 202, and the position sensor 218. The processing unit 204 and the position sensor 218 may provide information to the lithography controller 222 regarding the substrate processing and the substrate aligning. For example, the processing unit 204 may provide information to the lithography controller 222 to alert the lithography controller 222 that substrate processing has been completed. The lithography controller 222 facilitates the control and automation of a maskless lithography process based on a design file provided by the interface 230. The design file (or computer instructions), which may be referred to as an imaging design file, readable by the lithography controller 222, determines which tasks are to be performed on a substrate. The design file (e.g., the design file 420 of FIG. 4) includes a mask pattern data. The mask pattern data includes a mask pattern 300 and code to monitor and control the processing time and substrate position. The mask pattern 300 corresponds to a pattern to be written using the electromagnetic radiation.

The packaging substrate 220 comprises any suitable material, for example, glass. In other embodiments, which can be combined with other embodiments described herein, the packaging substrate 220 is made of other materials capable of being used as a part of the flat panel display or advanced packaging. The packaging substrate 220 has a film layer to be patterned formed thereon, such as by pattern etching thereof, and a photoresist layer 250 formed on the film layer to be patterned, which is sensitive to electromagnetic radiation, for example UV or deep UV “light”. A positive photoresist includes portions of the photoresist, when exposed to radiation, are respectively soluble to a photoresist developer applied to the photoresist after the pattern is written into the photoresist using the electromagnetic radiation. After exposure of the photoresist to the electromagnetic radiation, the resist is developed to leave a patterned photoresist on the underlying film layer. Then, using the patterned photoresist, the underlying thin film is pattern etched through the openings in the photoresist to form a portion of the packaging circuitry.

The processing unit 204 is supported by the support 208 such that the processing unit 204 straddles one of the track motors 216. The support 208 provides an opening 212 for the track motors 216 and the chuck 214 to pass under the processing unit 204. The processing unit 204 is a pattern generator configured to receive the mask pattern data from the interface 230 and expose the photoresist in the maskless lithography process using one or more image projection systems 206 operable to project write beams of electromagnetic radiation to the packaging substrate 220. The pattern generated by the processing unit 204 is projected by the image projection systems 206 to expose the photoresist of the packaging substrate 220 to the mask pattern that is written into the photoresist. In one embodiment, which can be combined with other embodiments described herein, each image projection system 206 includes a spatial light modulator to modulate the incoming light to create the desired image. Each spatial light modulator includes a plurality of electrically addressable elements that may be controlled individually. Each electrically addressable element may be in an “ON” position or an “OFF” position based on the mask pattern data and corrections provided by positional correction models created through the digital dynamic connection method 600 described herein. When the light reaches the spatial light modulator, the electrically addressable elements that are in the “ON” position project a plurality of write beams to a projection lens (not shown). The projection lens then projects the write beams to the packaging substrate 220. The electrically addressable elements include, but are not limited to, digital micromirrors, liquid crystal displays (LCDs), liquid crystal over silicon (LCoS) devices, ferroelectric liquid crystal on silicon (FLCoS) devices, microshutters, microLEDs, VCSELs, liquid crystal displays (LCDs), or any solid state emitter of electromagnetic radiation.

FIG. 2B is a schematic, cross-sectional view of a lithography tool in accordance with one or more embodiments of the present disclosure. The lithography tool 200 may be utilized for photolithography or electron beam (e-beam) lithography. The lithography tool 200 includes a source 201 and a stage 202. The packaging substrate 220 is disposed on the stage 202. The stage 202 includes an actuator operable to rotate the packaging substrate 220 in order to scan the packaging substrate 220 in X and Y directions.

A mask 203 is a physical mask and includes one or more apertures 255 corresponding to mask pattern. A beam 210 is projected by the source 201 through the one or more apertures 255 to form a mask pattern in a resist layer 250 disposed over the packaging substrate 220. The mask 203 is coupled to an actuator (not shown) to scan in X and Y directions in order to pattern the entirety of the packaging substrate 220. In embodiments utilizing photolithography, the source 201 is a light source, and the beam 210 is a light beam.

FIG. 3A is a schematic view of a portion of a mask pattern 300 in accordance with one or more embodiments of the present disclosure. FIG. 3B is a cross-sectional view of a layer structure 301 with a theoretical die pad position 306, i.e. expected location of a die pad on a die (not shown) in accordance with one or more embodiments of the present disclosure. The mask pattern 300 to be written into the photoresist using the processing unit 204. The mask pattern data includes a via mask pattern 307, a redistributed metal layer (RDL) mask pattern 303, and a die pad mask pattern 305. The via mask pattern 307 includes one or more via positions 302, i.e. expected via location. The RDL mask pattern 303 includes one or more RDL positions 304. The die pad mask pattern 305 includes one or more theoretical die pad positions 306. Each of the via positions 302 includes a center x-coordinate and y-coordinate (x,y)₃₀₂, each of the RDL positions 304 includes a center x-coordinate and y-coordinate (x,y)₃₀₄, and each of the theoretical die pad positions 306 includes a center x-coordinate and y-coordinate (x,y)₃₀₆ such that the metrology device 104 can perform recipe-based measurements at defined positions before the packaging substrate 220 is processed via the maskless lithography tool 108.

In the layer structure 301, as shown in FIG. 3B, the via position 302 is centered above the theoretical die pad position 306. The RDL position 304 is centered above the via position 302. In FIG. 3B, the via position 302 center x-coordinate and y-coordinate (x,y)₃₀₂ and the RDL position 304 center x-coordinate and y-coordinate (x,y)₃₀₄ are aligned with theoretical die pad 306 center x-coordinate and y-coordinate (x, y)₃₀₆.

FIG. 4 is a schematic view of the interface 230 in accordance with one or more embodiments of the present disclosure. The interface 230 includes a computing device 410 and input/output (I/O) devices 430. The interface 230 may be utilized to at least one of optimize, verify, or update a design file (e.g., the design file 420). The interface 230 may be utilized to at least one of optimize, verify, or update the design file 420 per instructions and readable data of a Universal Metrology File (UMF) provide from one of the pattern generator 102, the metrology device 104, and the controller 110. The optimization, verification, and updating of the design file 420 is further described in operations of the digital dynamic connection method 600.

The computing device 410 may include a controller 412, a network interface 414, and memory 416. The controller 412 retrieves and executes programing data stored in the memory 416 and coordinates operations of other system components. Similarly, the controller 412 stores and retrieves application data residing in the memory 416. The controller 412 may be one or more central processing units (CPUs).

The memory 416 may store instructions and logic to be executed by the controller 412. Further, the memory 416 may be one or more of a random access memory (RAM) and a non-volatile memory (NVM). The NVM may be a hard disk, a network attached storage (NAS), and a removable storage device, among others. Further, the memory 416 may include a design application 418 and a design file 420.

The design application 418 at least one of optimizes, verifies, and updates the design data of the design file 420. The design application 418 may be controlled by the controller 412 to optimize, and/or update the design data of the design file 420.

The design file 420 may be stored within the memory 416 and is accessible by the controller 412 and the design application 418. The design file 420 includes the mask pattern data that is interpreted by the lithography controller 222 to pattern the photoresist disposed on the packaging substrate 220. The design file 420 may be provided in different formats. For example, the format of the design file 420 may be one of a GDS format, and an OASIS format, among others. The mask pattern data of the design file 420 includes the via mask pattern 307, the RDL mask pattern 303, and the die PAD mask pattern 306. Other data included in the design file includes exposure dosage data, exposure focus data, and image projection system (IPS) to IPS calibration data. The exposure dosage data corresponds to the dosage of the write beams to be projected to the photoresist. The exposure focus data corresponds to the focus of the each of the image projection systems 206. The IPS to IPS calibration data corresponds to the stitching of the image projection systems 206 such the entirety of the mask pattern 300 is projected. The design file 420 may be in the form of a Bitmap or similar file.

The I/O devices 430 may include one or more of a keyboard, display device, mouse, audio device, and a touch screen, among others. The I/O devices 430 may be utilized to enter information into the pattern generator 102 and/or output data from the pattern generator 102. For example, a user may use a keyboard and a pointing device to generate and/or adjust elements of the design file 420. In another embodiment, which can be combined with other embodiments described herein, the I/O devices 430, via the network interface 414 in communication with the communication links 101, are coupled to the controller 110. The pattern generator 102 being coupled to the controller provides for a computer-integrated manufacturing (CIM) procedure utilizing computers to control the entirety of the operations of the digital dynamic connection method 600 described herein.

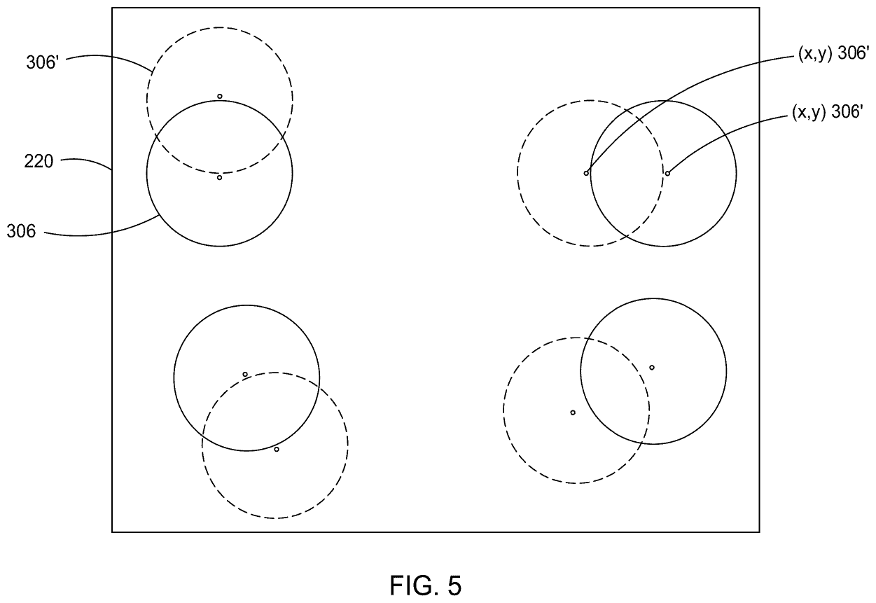

FIG. 5 is a schematic, top view of a packaging substrate 220 prior to a first operation of the digital dynamic connection method 600 described herein. During processing, the theoretical die pad position 306 may shift or rotate to a shifted die pad position 306′, i.e. measured location of the die pad. This shifting or rotation may be caused by pick, place, and molding. For example, the die pad 306 may have a shift from the theoretical die pad coordinates (x,y)₃₀₆ to a shifted x-coordinate and y-coordinate (x,y)₃₀₆′, i.e. determined die pad shift. As shown in FIG. 5, the theoretical die pad position 306 may shift to a shifted die pad position 306′ on the x-axis, the y-axis, or any angle on the x-y plane.

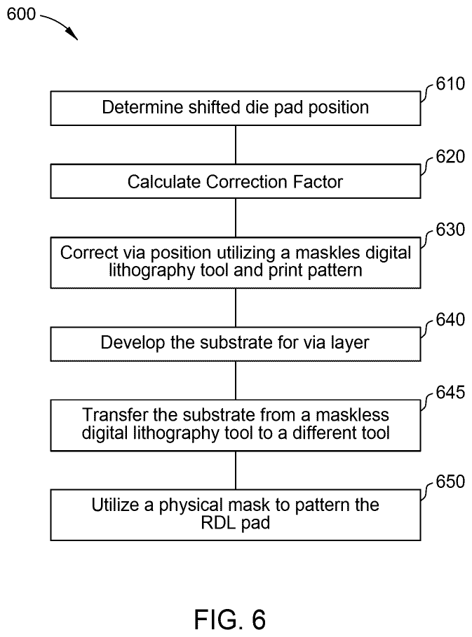

FIG. 6 is a flow diagram of the digital dynamic connection method 600 in accordance with one or more embodiments of the present disclosure. FIG. 7A is a schematic, top view of a layer structure 301 after the correction of the via position 302 to a partially shifted via position 302′, i.e. shifted via location, in accordance with one or more embodiments of the present disclosure. FIG. 7B is a schematic, cross-sectional view of a layer structure 301 in accordance with one or more embodiments of the present disclosure. In FIGS. 7A-7B, the die pad 306 is at a shifted die pad position 306′ with the shifted x-coordinate and y-coordinate (x,y)_{306′}. The RDL pad position 304 remains the same, without shifting. The via 302 is shifted to a shifted via position 302′ with a shifted x-coordinate and y-coordinate (x,y)_{302′}.

Operation 610 includes determining the shifted die pad position 306′. At operation 620, the correction factor is calculated. The amount the via position 302 needs to be shifted is calculated by measuring the amount of correction needed to match the shifted die pad 306′, and scaling those corrections down by a correction factor ξ. In some embodiments, the correction factor ξ is greater than zero and less than one. The correction factor ξ is calculated by the following equation:

$$\\ ξ = \frac{{OL}_{top}}{{OL}_{top} + {OL}_{bot}}$$

The top overlap OLₜₒₚ is the difference between the radius of the RDL pad r₃₀₄ and the radius of the via r₃₀₂. In embodiments where the via 302 is tapered, the top of the via is defined as the radius of the via r₃₀₂ for the calculation of the top overlap OLₜₒₚ. The bottom overlap OL_{bot} is defined as the difference between the die pad radius r₃₀₄ and the radius of the via r₃₀₂. In embodiments where the via 302 is tapered, the bottom of the via is defined as the radius of the via r₃₀₂ for the calculation of the bottom overlap OL_{bot}. The available correction range OLₜₒₜₐₗ is the difference between the theoretical die pad coordinates (x,y)₃₀₆ and the shifted die pad coordinates (x,y)_{306′}. In one embodiment, the RDL pad radius r₃₀₄ is 10 μm, the via radius r₃₀₂ is 5 μm, and the die pad radius r₃₀₆ is 15 μm. The top overlap OLₜₒₚ is 15 μm-5 μm=10 μm. The bottom overlap OL_{bot} is 20 μm-5 μm=15 μm. The correction factor ξ is 10 μm/(10μ+15 μm)=40%. Therefore, in this embodiment, the variation range of via pad position 302 is 40%×15 μm=6 μm.

FIG. 8A is a schematic, top view of a layer structure 301 without the RDL position 304 after the correction of the via position 302 to a completely shifted via position 302″, according to one embodiment of the present disclosure. FIG. 8B is a schematic, top view of a layer structure 301 without the RDL position 304 after the correction of the via position 302 to a partially shifted via position 302′, according to one embodiment of the present disclosure.

Operation 630 includes correcting the via position 302 and printing the via position 302 for electrically connecting the via 302 to the die pad 306. The via position 302 is corrected based on the correction factor ξ and the shifted die pad position 306′. As shown in FIG. 8A, the completely shifted via position 302″ has coordinates (x,y)_{302″} that align with the shifted die pad coordinates (x,y)_{306′}. As shown in FIG. 8B, the partially shifted via position 302′ has coordinates (x,y)_{302′} that are partially between the coordinates of the theoretical die pad coordinates (x,y)₃₀₆ and the shifted die pad coordinates (x,y)_{306′}. In some embodiments, the via position may be corrected via the maskless lithography tool 108.

FIG. 9A is a schematic, top view of a layer structure 301 after the correction of the via position 302 to a completely shifted via position 302″, according to one embodiment of the present disclosure. FIG. 9B is a schematic, top view of a layer structure 301 after the correction of the via position 302 to a partially shifted via position 302′, according to one embodiment of the present disclosure.

As shown in FIG. 9A, the completely shifted via position 302″ does not overlap with the RDL position 304. As shown in FIG. 9B, the partially shifted via position 302′ fully overlaps with the RDL position 304. Operation 640 includes developing the substrate for the via layer. Operation 645 includes transferring the substrate 220 from the maskless lithography tool 108 to the lithography tool 200. Operation 650 includes utilizing the mask pattern 300 to pattern the RDL pad 304. Since the RDL pad position 304 is untouched, the mask pattern 300 can be utilized to pattern the RDL pad 304. In some embodiments, the lithography tool 200 may be utilized to pattern the RDL pad 304.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
measuring a location of a die pad of a die placed on a substrate;
determining a die pad shift between an expected location of the die pad and the location of the die pad that is measured;
using the die pad shift that is determined and an expected via location to generate a shifted via location for a via electrically connecting to the die pad;
patterning a via at the shifted via location with a maskless lithography tool; and
utilizing a physical mask with a mask-based lithography tool to pattern a redistribution layer (RDL) pad electrically connected to the via patterned at the shifted via location with the maskless lithography tool.

2. The method of claim 1, wherein the shifted via location is calculated using a correction factor.

3. The method of claim 2, wherein the correction factor is calculated using a formula
$$\\ ξ = \frac{{OL}_{top}}{{OL}_{top} + {OL}_{bot}} ,$$
wherein OLₜₒₚ is a difference between a radius of the RDL pad and a top radius of the via, and OL_{bot} is a difference between a die pad radius and a bottom radius of the via.

4. The method of claim 3, wherein ξ is greater than zero and less than one.

5. The method of claim 1, wherein the shifted via location has a top surface area located beneath a surface area of the RDL pad.

6. The method of claim 1, wherein a bottom surface area of the shifted via location is located above a surface area of the die pad.

7. The method of claim 1, further comprising transferring the substrate from the maskless lithography tool to a lithography tool.

8. The method of claim 1, further comprising updating a design file comprising the expected via location with the shifted via location.

9. The method of claim 8, further comprising transferring the design file to the maskless lithography tool.

10. A layer structure, comprising:
one or more die pads, the one or more die pads each comprising a die pad center point;
one or more vias located above the one or more die pads, the one or more vias each comprising a via center point; and
one or more redistributed metal layer (RDL) pads located above the one or more vias, the one or more RDL pads each comprising a RDL pad center point, wherein the die pad center point, the via center point, and the RDL pad center point are unaligned, and the via center point is located between the RDL pad center point and the die pad center point.

11. A non-transitory computer-readable medium storing instructions that, when executed by a processor, cause a computer system to perform the steps of:
calculating a correction factor, the calculation comprising:
a via radius;
a redistributed metal layer (RDL) pad radius; and
a die pad radius;
determining one or more shifted die pad coordinates; and
moving one or more via coordinates utilizing the correction factor, each via coordinates being moved to shifted via coordinates between theoretical die pad coordinates and shifted die pad coordinates of the one or more shifted die pad coordinates.

12. The non-transitory computer-readable medium of claim 11, wherein the via radius is a top radius of a via, and the correction factor is calculated using the formula
$$\\ ξ = \frac{{OL}_{top}}{{OL}_{top} + {OL}_{bot}} ,$$
wherein OLₜₒₚ is a difference between the radius of the RDL pad and a top radius of the via and OL_{bot} is a difference between the die pad radius and a bottom radius of the via.

13. The non-transitory computer-readable medium of claim 11, wherein the one or more shifted die pad coordinates are determined using a maskless lithography tool.

14. The non-transitory computer-readable medium of claim 11, further comprising transferring a substrate from a maskless lithography tool to a mask-based lithography tool, wherein the via, the RDL pad, and the die pad are on the substrate.

15. The non-transitory computer-readable medium of claim 13, further comprising updating a design file with the shifted via coordinates.

16. The non-transitory computer-readable medium of claim 15, further comprising transferring the design file to the maskless lithography tool.

17. The non-transitory computer-readable medium of claim 11, wherein the one or more via coordinates are moved using a maskless lithography tool.

18. The non-transitory computer-readable medium of claim 11, further comprising patterning a redistribution layer (RDL) pad electrically connected to the via.

19. The non-transitory computer-readable medium of claim 18, wherein the RDL pad is patterned using a mask-based lithography tool.

20. The non-transitory computer-readable medium of claim 11, wherein a shifted via location at the shifted via coordinates has a top surface area located beneath a surface area of the RDL pad.
